(19) United States
(12) Patent Application Publication
(10) Pub. No.: US 2011/0073357 A1
(43) Pub. Date: Mar. 31, 2011

(54) ELECTRONIC DEVICE AND METHOD OF MANUFACTURING AN ELECTRONIC DEVICE

(75) Inventor: Christian Zenz, Graz (AT)

(73) Assignee: NXP B.V., Eindhoven (NL)

(21) Appl. No.: 12/995,848

(22) PCT Filed: May 13, 2009
(86) PCT No.: PCT/IB09/51966

§ 371 Date: Dec. 2, 2010

(30) Foreign Application Priority Data
Jun. 2, 2008 (EP) 08104214.5
May 13, 2009 (IB) PCT/IB2009/051966

(51) Int. Cl. H05K 1/09; H05K 1/16; H05K 3/36

(52) U.S. Cl. 174/257; 174/260; 29/830

(57) ABSTRACT

Electronic device comprising an integrated circuit (1) embedded into a substrate, wherein the substrate has at least a first (3) and a second (9) conductive structure arranged on opposite sides of the integrated circuit (1) and the electrical connections (10,11,12,13) between the first (3) and the second (9) conductive structure and/or with the integrated circuit 5 (1) are established by means of holes (8) in the substrate.

### FIELD OF THE INVENTION

The invention relates to an electronic device comprising an integrated circuit embedded into a substrate.

Further, the invention relates to a method of manufacturing an electronic device.

### BACKGROUND OF THE INVENTION

Electronic devices within the scope of the present invention and in particular smartcards for radio frequency identification (RFID) applications usually consist of an integrated circuit (IC), packaged in a module, which is then connected with an antenna and subsequently integrated into a cardbody. For standard cards, normally the module is attached to a substrate foil, in which the insulated wire antenna is embedded and attached by a welding process to the module. This substrate foil then is called an inlay, which, in a separate step, is laminated into the final RFID card.

An alternative way of producing an inlay uses a so-called direct chip attach process. In that case, the antenna consists of a structured layer of a conductive material, such as a thin metal foil, conductive ink, a galvanic plated layer etc., and the integrated circuit is connected directly to the antenna via, e.g., a flip chip process.

For example in WO 2007/075352 A2 there is disclosed a method for the assembly of electrical devices and in particular for the assembly of RFID interposers and/or devices. This known method includes heat embedding a chip having bond pads (e.g. bumps) in a substrate and coupling the chip to an antenna element on an upper surface of said substrate. In such a process, the step of providing the antenna structure on a surface of the substrate layer and the step of contacting the antenna structure with the chip are separate, thereby giving rise to procedural inconvenience.

In order to couple the chip with the antenna structure the assembly is compressed. During compression the bumps of the chip penetrate the substrate to establish contact with the antenna structure on the upper surface of the substrate. During compression, considerable stress is applied to the chip in the region of the bond pads or bumps so that delicate structures of the chip should not be arranged in the region neighbouring or underlying the bumps area and the chip in general should have a thickness sufficient to offer the necessary strength.

In all the described approaches, the actual transponder inlay is not flat, so that additional layers have to be added to compensate for the thickness differences to give a prelam, which then again can be laminated or glued into the final card. Structures using modules currently result in a minimum thickness of around 300 μm. Structures using direct chip attach reveal the disadvantage that the IC is more or less unprotected during the lamination process, which limits the IC thickness to around 100 μm in order to give reasonable die strength values. Assuming a flip chip process, additional bumps are required, which also can be seen as critical for mechanical reliability of the final product, since the stress concentration underneath the bumps is high.

Another problem is the antenna production, and in particular the establishing of a bridge for connecting the two ends of the antenna. Antennas for smart card inlays are usually produced by printing or etching. Then, the integrated circuit is directly connected to the antenna (direct chip attach), whereby the bridging is done in different ways. If the antenna is produced by printing, usually an insulating layer and an additional track has to be printed in additional process steps for establishing the bridge. If the antenna is produced by etching, both sided of the antenna substrates are patterned and then electrically connected.

Alternatively, the integrated circuit is packaged into a module or an interposer, requiring electrical connection from the integrated circuit to the leads of the module (e.g. by wire bonding) or interposer (flip chip process). In that case, the interposer can also be used as a bridge.

The common problem to all manufacturing methods as described above is that the antenna production process requires several steps. In case an interposer or moduler is used, the manufacturing process is even more complicated, because also additional interconnects between the integrated circuit and the leads and between the leads and the antenna have to be made. Especially for the realization of ultra-thin inlays or prelams the handling of thin integrated circuits is difficult. Additionally, thin integrated circuits are known to be light sensitive, so that protective layers may have to be applied.

Hence, it is an object of the invention to provide an electronic device, in particular for use in smartcards for RFID applications, which has an improved antenna bridge design and which at the same time stands out for its simple, robust and particularly slim construction. Further, the production of the electronic device shall be easy and cost effective and in particular the amount of process steps shall be reduced.

Hence, a further object of the invention is to provide a method of manufacturing the electronic device, in particular for use in smartcards for RFID applications, which use a minimum of process steps and which solves the existing problems regarding the bridging of the antenna.

### OBJECT AND SUMMARY OF THE INVENTION

The object of the invention is achieved by an electronic device as set forth in claim 1.

The object of the invention is furthermore achieved by a method of manufacturing an electronic device as set forth in claim 14.

Additional advantages of the present invention are achieved by the features as set forth in the dependent claims.

According to the invention the electronic device comprises an integrated circuit embedded into a substrate, wherein the substrate has at least a first and a second conductive structure arranged on opposite sides of the integrated circuit and the electrical connections between the first and the second conductive structure and/or with the integrated circuit are established by means of holes in the substrate. By having a configuration, where the integrated circuit as well as the first and the second conductive structure are arranged and realized in the substrate, a particularly compact design is achieved, wherein the integrated circuit is totally protected from external impacts. Because the first and the second conductive structure are arranged on opposite sides of the integrated circuit it is feasible to have, e.g., antenna structures arranged directly on or in the substrate, whereby it is of particular advantage, if, in accordance with a preferred embodiment of the invention, the first conductive structure forms a conductive bridge between two regions of the second conductive structure. Thus, one of the conductive structures can form the antenna and the other conductive structure, being on the opposite side of the integrated circuit, can form the bridge to connect two distant ends or regions of the antenna. The bridge is just realized as an additional layer in the substrate and does not significantly add to the complexity of the design. At the same time, the bridging layer can serve to add stability to the substrate and can function as a protective layer for the integrated circuit. In particular, the bridging layer can serve to protect the integrated circuit from light exposure during production.

According to the invention the connection between the first and the second conductive structure and/or with the integrated circuit is established by means of holes in the substrate, which results in that the connecting paths are completely protected by and embedded in the substrate. Moreover, the electrical connection does not require any bumps to be present on the integrated circuit, because the conductive medium to be introduced into the holes can directly be brought into contact with respective contacting surfaces of the structure to be electrically connected, which results in a particularly thin structure. Another advantage is that there is no need of a metal interconnection between the structures for them to be electrically connected.

Holes can be arranged to electrically connect either the second conductive structure with the first conductive structure or the second conductive structure with the integrated circuit or both. In this connection, a preferred embodiment of the inventive device is achieved, if the substrate comprises at least one hole above a contacting surface of the integrated circuit for electrically connecting the second conductive structure with the integrated circuit. Correspondingly, according to a preferred embodiment, the substrate comprises at least one hole above a contacting surface of the first conductive structure for electrically connecting the first conductive structure with the second conductive structure. Depending on the size of the contacting surfaces the positioning tolerances for the integrated circuit on the layer having the first conductive structure and the positioning tolerance of the second conductive structure relative to the integrated circuit can be higher when compared to prior art designs.

A particularly simple design is achieved if the substrate is built as a layer composition. A preferred embodiment, therefore, provides for a composition, wherein the integrated circuit is arranged between two layers of the substrate, the second conductive structure being arranged on a surface of at least one substrate layer facing away from the integrated circuit and the first conductive structure being arranged on the surface of at least one substrate layer facing the integrated circuit. In such an embodiment the conductive structures again are arranged on opposite sides of the integrated circuit, whereby the second conductive structure, e.g., is arranged on the exterior surface of the substrate and the first conductive structure, as is the case for the integrated circuit, is arranged between the two substrate layers, the integrated circuit advantageously being positioned above the first conductive structure.

In this connection, a preferred embodiment is characterized in that the first conductive structure is designed as a conductive layer separated from the integrated circuit by an insulating layer. The insulating layer can at the same time function as an adhesive for fixing the integrated circuit on the conductive layer. The conductive layer can be a metal carrier or any other kind of conductive material. However, if the conductive layer is not selected to be a metal carrier, usually an additional substrate for the conductive layer is needed. Therefore, according to a preferred embodiment, the conductive layer is arranged on a carrier, in particular a polymer carrier. In this way, the carrier can act as protecting layer and can also enhance the rigidity of the inventive device. The conductive layer being either a metal carrier or a non-conductive carrier coated with a conductive layer results in a particularly thin design.

For using the inventive device as an inlay for RFID smart cards an embodiment is advantageous, wherein the second conductive structure comprises at least one conductive trace in a spiral-like form. Such a structure results in a particularly efficient use of the available surface area, whereby both ends of the spiral-like trace can be connected with each other by the bridge being formed by the first conductive structure. In this way, according to a preferred embodiment, the first and the second conductive structure together form an antenna, such as an antenna for RFID applications. In a particularly advantageous manner, the second conductive structure can comprise two separate conductive traces in spiral-like form, both traces being arranged essentially concentrically, whereby the bridge connects the inner end of the inner trace with the outer end of the outer trace. In other words, this configuration can also be described as a single spiral-like trace that is separated in two spiral-like regions, whereby the separation points are connected to the integrated circuit, the connection being preferably established via the holes.

The production of the second conductive structure can be achieved in different ways as know from the state of the art. A particularly simple manufacturing method, however, can be obtained if, in accordance with a preferred embodiment, the second conductive structure is made of conductive ink and the electrical connections between the first and the second conductive structure and/or with the integrated circuit are established by means of conductive ink filling the holes in the substrate. In this way, the application of the second conductive structure, such as the antenna, and the electrical connection to the first conductive structure and/or the integrated circuit can be performed in a single process step, thus resulting in a very efficient manufacturing method.

Alternatively, the electrical connections between the first and the second conductive structure and/or with the integrated circuit can be established by means of a conductive paste or a conductive adhesive filling the holes in the substrate.

As mentioned above, the inventive device, due to its very low structural height, is particularly suitable for integration into smart cards. Therefore, according to a preferred embodiment, the device is arranged as an inlay for smart cards.

In this connection it is of further advantage, if the substrate is made from thermoplastic material.

The inventive method comprises the steps of:
arranging an integrated circuit on a layer having a first conductive structure,
embedding the integrated circuit into a substrate,
forming holes in the substrate,
forming a second conductive structure on a surface of the substrate, said surface being on a side of the integrated circuit opposite to the first conductive structure,
electrically connecting the second conductive structure to the first conductive structure and/or to the integrated circuit by means of the holes.

Thus, with a minimum of process steps the integrated circuit can be embedded and the conductive structures, such as an antenna for RFID applications, can be formed and electrically connected to the integrated circuit. Due to the inventive design, where there is a first and a second conductive structure on opposite sides of the integrated circuit, one conductive structure can serve to connect distant ends or regions of the first conductive structure, so that, in accordance with a preferred embodiment, the first conductive structure forms a conductive bridge between two regions of the second conductive structure. Since the first conductive structure is in the form of an additional layer integrated into the module, no further step of isolating a region of the second conductive structure is necessary to form a bridge between the two regions of the second conductive structure to be connected.

The structure resulting from inventive manufacturing method is already robust and no compression of this structure will be necessary for connecting the integrated circuit to the second conductive structure as in the prior art. It is rather proceeded such that holes are formed in the substrate, e.g. by laser drilling, so that subsequent electrical connection of the conductive structures can be achieved by means of the holes.

According to a particularly preferred embodiment of the present invention, said step of forming the second conductive structure and said step of connecting the second conductive structure are performed in a single process step. This is in a particularly simple and efficient manner feasible, when said step of forming a second conductive structure, as in accordance with a preferred embodiment, comprises printing said structure with a conductive ink and during said printing filling said holes with ink thereby connecting the second conductive structure with the first conductive structure and/or with the integrated circuit. Thus, the number of process steps can be further reduced and the manufacturing method becomes appropriate for mass production.

Alternatively, said step of forming the second conductive structure may comprise structuring and etching the substrate to form metallic conducting paths. These techniques can be carried out using existing appliances. In this connection, said step of connecting said second structure, as in accordance with a preferred embodiment of the present invention, comprises applying a conductive paste or a conductive adhesive into the holes. This method for establishing electrical connection between the conductive structures or the conductive structures and the integrated circuit, respectively, can be used with practically all methods of forming the second conductive structure. Alternatively, said step of connecting said second structure can be done by soldering or electro-galvanic deposition.

According to a preferred embodiment of the present invention, said step of embedding comprises laminating the integrated circuit between two layers of the substrate. By providing the substrate in the form of layers, the various components of the inventive device can be subsequently arranged, which provides for a simple process of production. In this connection, it is advantageous when the first conductive structure is formed on a surface of at least one substrate layer facing away from the integrated surface and the second conductive structure is formed on a surface of at least one substrate layer facing the integrated circuit. In such a method, the conductive structures are arranged on opposite sides of the integrated circuit, whereby the second conductive structure, e.g., is arranged on the exterior surface of the substrate and the first conductive structure, as is the case for the integrated circuit, is arranged between the two substrate layers.

Alternatively to forming the second conductive structure and connecting the second conductive structure in a single process step, it is also conceivable that said step of forming the second conductive structure is performed prior to the step of embedding the integrated circuit. This makes it possible to form the second conductive structure in a separate step and, as the case may be, at a separate location, so that the substrate layer with the pre-formed conductive structure arranged thereon can be supplied to the embedding step. In this case, the step of connecting the second conductive structure of course takes place after the embedding step.

Before carrying out the step of connecting the second conductive structure it is required to form the holes into the substrate. In a particularly advantageous embodiment of the invention, said step of forming holes comprises laser drilling, which provides a highly accurate method of forming said holes in the substrate even where the integrated circuit has already been embedded into the substrate. Alternatively, said step of forming holes is performed before said step of embedding the integrated circuit into the substrate, which provides the advantage that the holes can be made without the danger of damaging the integrated circuit. According to a further alternative embodiment, the holes can be formed during the step of embedding, and in particular by providing bond pads or bumps on the integrated circuit, which are pressed into the substrate layer when the integrated circuit is compressed between two layers of the substrate, thereby forming the holes for connecting the bond pads or bumps to the second conductive structure. Such a method is, e.g., described in WO 2007/075352 A2.

According to a preferred embodiment of the present invention, the integrated circuit comprises contacting surfaces and the first conductive structure comprises contacting surfaces and the holes are formed in the substrate above the contacting surfaces. In this case the second conductive structure can be directly connected to the first conductive structure and the integrated circuit via the holes, whereby depending on the size of the contacting surfaces the provision of contacting surfaces leads to greater positioning tolerances of the integrated circuit on the first conductive structure and relative to the holes above the contacting surfaces as compared to the prior art. The contacting surfaces can be realized on bond pads or bumps of the integrated circuit, but in a preferred embodiment the surfaces are lying in the plane of the IC surface and thus do not protrude from the IC surface. In this way, the integrated circuit is not subjected to mechanical stress peaks in the region of the contacting surfaces when being compressed between the substrate layers so that the danger of damaging delicate structures of the integrated circuit is minimized.

According to a preferred embodiment of the present invention, the layer having the first conductive structure is selected to be a conductive layer. Preferably, the conductive layer is arranged on a carrier, in particular a polymer carrier. The layer having the first conductive structure can hence be made of a material offering the required strength, whereby an especially thin overall design is achieved.

In a particularly advantageous manner of carrying out the inventive method, said step of arranging the integrated circuit on the layer having the first conductive structure comprises interposing an insulative layer between the integrated circuit and the first conductive structure. This adds to the mechanical strength of the device and results in the required electrical separation between the first conductive structure and any exterior conducting parts of the integrated circuit. Further, if the insulating layer at the same time functions as an adhesive, this facilitates the subsequent handling of the integrated circuit. In particular, the integrated circuit being fixed to layer having the first conductive structure can more easily be picked and handled by automated picking devices in a automated production environment.

As in accordance with a preferred embodiment of the present invention, said step of forming the second conductive structure comprises applying at least one conductive trace on the substrate in a spiral like form, which allows for an efficient use of the space available on the substrate. Preferably, the second conductive structure forms an antenna, such as an antenna for RFID applications. In this case, the first conductive structure serves as a bridge for connecting the two ends of the coil-like antenna.

In a preferred embodiment of the present invention, the substrate is made from thermoplastic material, whereby a lamination-process employing heat to soften the thermoplastic material can result in a flat module containing all components of the electronic device. In this connection, the substrate preferably is designed to form an inlay for a smartcard.

These and other aspects of the invention are apparent from and will be elucidated with reference to the embodiments described hereinafter.

### BRIEF DESCRIPTION OF THE DRAWINGS

The invention will be described in greater detail hereinafter, by way of non-limiting examples, with reference to the embodiments shown in the drawings.

FIG. 1 shows the arrangement of an integrated circuit on a first conductive structure in a sectional view;

FIG. 2 shows the arrangement of FIG. 1 in a plan view;

FIG. 3 shows the arrangement of FIG. 1 embedded in a substrate in a sectional view;

FIG. 4 shows the arrangement of FIG. 3 with holes for connecting the conductive structures with each other in a sectional view;

FIG. 5 shows the electronic device with first and second conductive structures being connected with each other in a sectional view and

FIG. 6 shows the electronic device of FIG. 5 in a plan view, FIG. 5 being a section along the lines V-V of FIG. 6.

### DESCRIPTION OF EMBODIMENTS

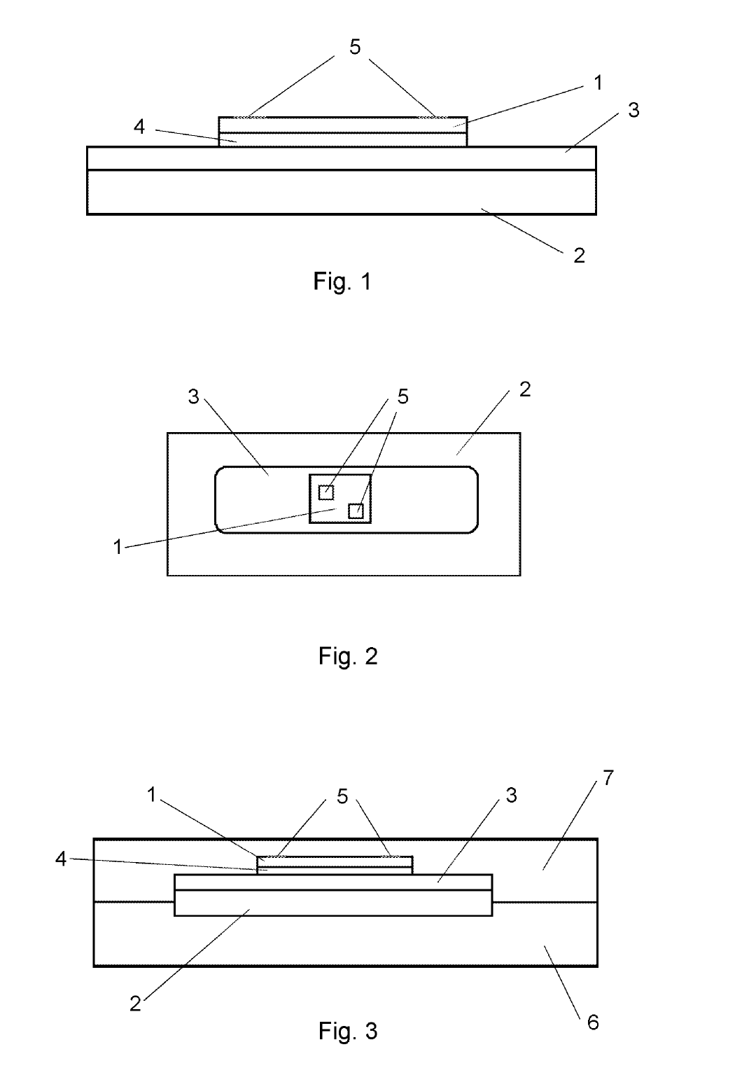

In FIG. 1, an IC 1, by interposition of an isolating layer 4, is in a first process step placed on a first conductive structure, which in this case is a conductive layer 3 arranged on a carrier 2, such as a polymer carrier. The isolating layer 4 also functions as an adhesive for firmly holding the IC 1 on the conductive layer 3. From a process point of view the handling of the IC 1 being fixed onto the carrier 2 is much easier than a direct pick and place process and can be easily integrated into an antenna production and lamination environment. This first process step is similar to IC packaging for an interposer, but without the need of a metal interconnection between the IC and the conductive parts of the carrier and much relaxed positioning tolerances. In the top view according to FIG. 2 it can be seen that the conductive layer 3 can be patterned in a way to optimize the following process steps. In particular it will be realized that the exact positioning of the IC 1 on the conductive layer 3 is not critical, since the conductive layer 3 will offer sufficient area for subsequent contacting of the second conductive structure to be applied in a later stage of the process. Also the electrical contacting surfaces 5 of the IC 1 are sufficiently large to allow for a certain positioning tolerance of the second conductive structure.

In FIG. 3 it can be seen that in a second process step the carrier 2 with the IC 1 arranged thereon is embedded between two layers 6 and 7 of a substrate in order to give a closed structure. The carrier 2 can be either directly applied to the substrate material or laminated between the substrate layers.

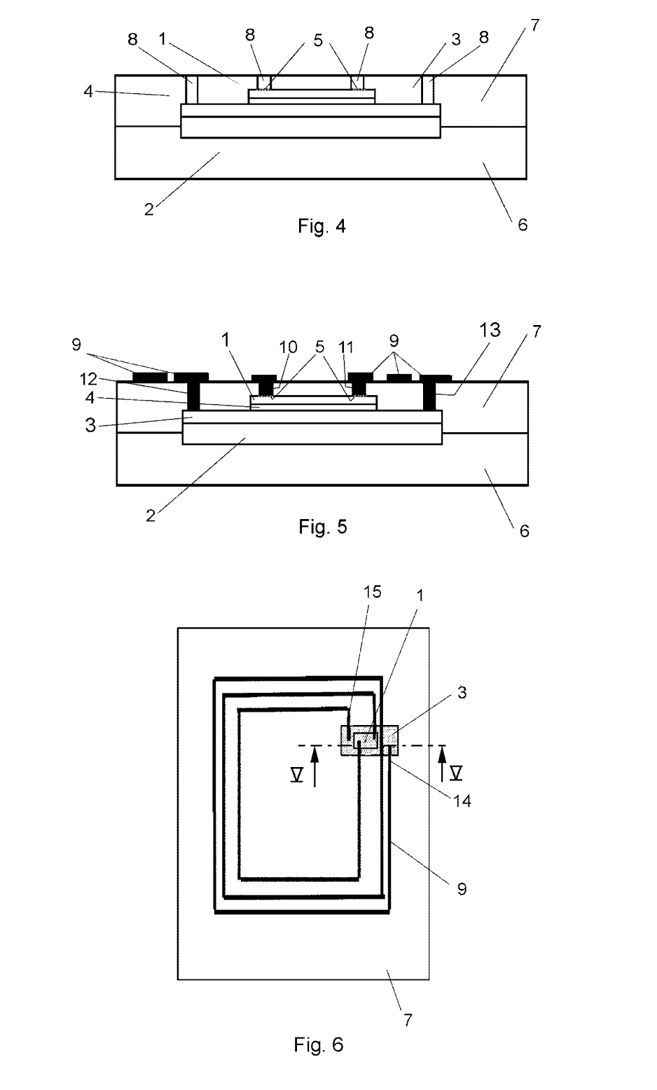

In a further process step, as can be seen in FIG. 4, the substrate material is opened by, e.g., laser drilling holes 8 above the contacting surfaces 5 of the IC 1 and above the conductive layer 2 or contacting surfaces thereof. Alternatively, it is also possible to punch the holes in the substrate layer 7 before the step of embedding.

Subsequently, the second conductive structure 9 is applied on the upper surface of the substrate layer 7, for example by printing the structure onto the substrate layer 7 with a conductive ink and at the same time filling the holes 8 in order to establish electrical connections 10 and 11 between the second conductive structure 9 and the IC 1 as well as electrical connections 12 and 13 between the second conductive structure 9 and the first conductive structure 3.

FIG. 6 shows a final inlay, such as an inlay for smartcards. From the top view according to FIG. 6 it can be seen that the second conductive structure 9 has been applied as a spiral-like conductive trace to form an antenna, such as an antenna for RFID applications.

The antenna is connected to the IC 1 by means of the electrical connections 10 and 11. The two distant ends 14 and 15 of the antenna are connected to the conductive layer 3 by means of the electrical connections 12 and 13, so that the conductive layer 3 forms a conductive bridge between the ends 14 and 15 of the antenna.

Finally, it should be noted that the above-mentioned embodiments illustrate rather than limit the invention, and that those skilled in the art will be capable of designing many alternative embodiments without departing from the scope of the invention as defined by the appended claims. In the claims, any reference signs placed in parentheses shall not be construed as limiting the claims. The word “comprise” and its conjugations do not exclude the presence of elements or steps other than those listed in any claim or the specification as a whole. The singular reference of an element does not exclude the plural reference of such elements and vice-versa. In a device claim enumerating several means, several of these means may be embodied by one and the same item of software or hardware. The mere fact that certain measures are recited in mutually different dependent claims does not indicate that a combination of these measures cannot be used to advantage.

1. Electronic device comprising an integrated circuit embedded into a substrate, wherein the substrate has at least a first and a second conductive structure arranged on opposite sides of the integrated circuit (1) and the electrical connections between the first and the second conductive structure and/or with the integrated circuit are established by means of holes in the substrate.

2. Electronic device according to claim 1, wherein the first conductive structure forms a conductive bridge between two regions of the second conductive structure.

3. Electronic device according to claim 1, wherein the integrated circuit is arranged between two layers of the substrate, the second conductive structure being arranged on a surface of at least one substrate layer facing away from the integrated circuit and the first conductive structure being arranged on a surface of at least one substrate layer facing the integrated circuit.

4. Electronic device according to claim 1, wherein the first conductive structure is designed as a conductive layer separated from the integrated circuit by an insulating layer.

5. Electronic device according to claim 4, wherein the conductive layer is arranged on a polymer carrier.

6. Electronic device according to claim 1, wherein the second conductive structure is made of conductive ink and the electrical connections between the first and the second conductive structure and/or with the integrated circuit are established by means of conductive ink filling the holes in the substrate.

7. Electronic device according to claim 1, arranged as an inlay for smart cards.

8. Method of manufacturing an electronic device, comprising:
arranging an integrated circuit (1) on a layer (6) having a first conductive structure,
embedding the integrated circuit into a substrate,
forming holes in the substrate,
forming a second conductive structure on a surface of the substrate, said surface being on a side of the integrated circuit opposite to the first conductive structure,
electrically connecting the second conductive structure to the first conductive structure and/or to the integrated circuit by means of the holes.

9. Method according to claim 8, wherein forming the second conductive structure and connecting the second conductive structure are performed in a single process step.

10. Method according to claim 8, wherein forming said second conductive structure comprises printing said structure with a conductive ink and during said printing filling said holes with ink thereby connecting the second conductive structure with the first conductive structure and/or with the integrated circuit.

11. Method according to claim 8, wherein embedding comprises laminating the integrated circuit between two layers of the substrate.

12. Method according to claim 8, wherein arranging the integrated circuit on the layer having the first conductive structure comprises interposing an insulative layer between the integrated circuit and the first conductive structure.

13. Method according to claim 8, wherein the second conductive structure forms an antenna for RFID applications.
